(19) United States
(12) Patent Application Publication
(10) Pub. No.: US 2023/0363202 A1
(43) Pub. Date: Nov. 9, 2023

(54) DISPLAY SUBSTRATE, DISPLAY PANEL AND DISPLAY DEVICE

(71) Applicant: BOE TECHNOLOGY GROUP CO., LTD., Beijing (CN)

(72) Inventors: Jinxiang XUE, Beijing (CN); Zhongyuan SUN, Beijing (CN); Guoqiang WANG, Beijing (CN); Wenqi LIU, Beijing (CN); Jingkai NI, Beijing (CN); Che AN, Beijing (CN)

(21) Appl. No.: 17/613,998

(22) PCT Filed: Dec. 18, 2020
(86) PCT No.: PCT/CN2020/137560

§ 371 Date: Jun. 23, 2022

(51) Int. Cl. H10K 59/12; H10K 59/131; H10K 59/127; H10K 59/80

(52) U.S. Cl. CPC H10K 59/1201; H10K 59/131; H10K 59/127; H10K 59/87; H10K 2102/3026

(57) ABSTRACT

The present disclosure provides a display substrate, which includes a base substrate, and a display unit, a connection unit and a hollowed-out unit, which are adjacent to each other, on the base substrate; the display unit includes a first insulating part and a conductive part; the connection unit includes a second insulating part and a conductive connecting part, the second insulating part is arranged on a side of the conductive connecting part away from the base substrate; the conductive connecting part is in contact with the base substrate, extends from an area of the base substrate where the connection unit is located to an area of the base substrate where the display unit is located, and is electrically coupled to the conductive part through a via hole formed in the first insulating part; the second insulating part has a tensile property superior to the first insulating part.

### TECHNICAL FIELD

Embodiments of the present disclosure relate to the field of display technology, and particularly relate to a display substrate, a display panel and a display device.

### BACKGROUND

Currently, OLED flexible display devices capable of being bent and folded are being actively developed, and further, stretchable OLED display devices are a development direction of future display technologies.

Although the substrate, circuit layers, inorganic insulating layers and encapsulation layers in the OLED flexible display device have certain flexibility, the stretching amount of the substrate, the circuit layers, the inorganic insulating layers and the encapsulation layers is extremely limited, and if the OLED flexible display device is directly stretched, the substrate, the circuit layers, the inorganic insulating layers and the encapsulation layers in the OLED flexible display device may be cracked, broken or irreversibly deformed to different degrees, so that the display quality of the display device is seriously affected, and the stretching of the display device cannot be well realized.

### SUMMARY

The embodiments of the present disclosure provide a display substrate, a display panel and a display device.

In a first aspect, an embodiment of the present disclosure provides a display substrate, including a base substrate, and a display unit, a connection unit, and a hollowed-out unit disposed on the base substrate, where the display unit, the connection unit, and the hollowed-out unit are adjacent to each other;
the display unit includes a first insulating part and a conductive part; the connection unit includes a second insulating part and a conductive connecting part, where the second insulating part is arranged on a side of the conductive connecting part away from the base substrate;
the conductive connecting part is in contact with the base substrate, extends from an area of the base substrate where the connection unit is located to an area of the base substrate where the display unit is located, and is electrically coupled to the conductive part through a via hole formed in the first insulating part;
the second insulating part has a tensile property superior to that of the first insulating part.

In some implementations, the conductive part includes a driving circuit and a light emitting element, the light emitting element being located on a side of the driving circuit away from the base substrate; the driving circuit is electrically coupled to the light emitting element and is configured to drive the light emitting element to emit light;
the conductive connecting part includes at least one of a data line, a scan line, a power supply signal line and a control signal line;
the data line, the scan line, the power supply signal line and the control signal line are respectively electrically coupled to the driving circuit;
the data line is configured to provide a data signal for driving the light emitting element to emit light;
the scan line is configured to provide a scan signal for driving the light emitting element to emit light;
the power supply signal line is configured to provide a power supply signal for driving the light emitting element to emit light;
the control signal line is configured to provide a control signal for driving the light emitting element to emit light.

In some implementations, the driving circuit includes a driving transistor including a first gate electrode, a second gate electrode, an active layer, a source electrode, and a drain electrode; each of orthographic projections of the first gate electrode and the second gate electrode on the base substrate is within an orthographic projection of the active layer on the base substrate; orthographic projections of the source electrode and the drain electrode on the base substrate are respectively positioned at two opposite ends of the orthographic projection of the active layer on the base substrate;
the first insulating part includes a first insulating layer, a buffer layer, a first gate insulating layer, a second gate insulating layer, an intermediate dielectric layer and a planarization layer which are sequentially stacked in a direction away from the base substrate;
the active layer is positioned between the buffer layer and the first gate insulating layer; the first gate electrode is positioned between the first gate insulating layer and the second gate insulating layer; the second gate electrode is positioned between the second gate insulating layer and the intermediate dielectric layer; the source electrode and the drain electrode are located between the intermediate dielectric layer and the planarization layer;
the light emitting element is arranged on a side of the planarization layer away from the base substrate, and includes a first electrode, a light emitting functional layer and a second electrode which are sequentially stacked;
the drain electrode is electrically coupled to the first electrode through a via hole formed in the planarization layer.

In some implementations, the conductive connecting part extending from the area where the connection unit is located to the area where the display unit is located is disposed between the first insulating layer and the base substrate;
the second insulating part includes a second insulating layer, and the second insulating layer and the planarization layer are made of a same material.

In some implementations, the driving circuit further includes a third electrode disposed between the intermediate dielectric layer and the planarization layer, and the third electrode is electrically coupled to the drain electrode;
the conductive connecting part includes the data line, and the data line extending from the area where the connection unit is located to the area where the display unit is located is electrically coupled to the third electrode through via holes formed in the first insulating layer, the buffer layer, the first gate insulating layer, the second gate insulating layer and the intermediate dielectric layer.

In some implementations, the driving circuit further includes a third electrode and a fourth electrode, the third electrode is disposed between the intermediate dielectric layer and the planarization layer, and the third electrode is electrically coupled to the drain electrode;
the fourth electrode is arranged between the first gate insulating layer and the second gate insulating layer, and the fourth electrode and the first gate electrode are made of a same material;
the conductive connecting part includes the data line, the data line extending from the area where the connection unit is located to the area where the display unit is located is electrically coupled to the fourth electrode through via holes in the first gate insulating layer, the buffer layer and the first gate insulating layer, and the fourth electrode is electrically coupled to the third electrode through via holes in the second gate insulating layer and the intermediate dielectric layer.

In some implementations, the driving circuit further includes a third electrode and a fourth electrode, the third electrode is disposed between the intermediate dielectric layer and the planarization layer, and the third electrode is electrically coupled to the drain electrode;
the fourth electrode is arranged between the second gate insulating layer and the intermediate dielectric layer, and the fourth electrode and the second gate electrode are made of a same material;
the conductive connecting part includes the data line, the data line extending from the area where the connection unit is located to the area where the display unit is located is electrically coupled to the fourth electrode through via holes in the first gate insulating layer, the buffer layer, the first gate insulating layer and the second gate insulating layer, and the fourth electrode is electrically coupled to the third electrode through a via hole in the intermediate dielectric layer.

In some implementations, the driving circuit further includes a third electrode, a fourth electrode and a fifth electrode, the third electrode is disposed between the intermediate dielectric layer and the planarization layer, and the third electrode is electrically coupled to the drain electrode;
the fourth electrode is arranged between the second gate insulating layer and the intermediate dielectric layer, and the fourth electrode and the second gate electrode are made of a same material;
the fifth electrode is arranged between the first gate insulating layer and the second gate insulating layer, and the fifth electrode and the first gate electrode are made of a same material;
the conductive connecting part includes the data line, and the data line extending from the area where the connection unit is located to the area where the display unit is located is electrically coupled to the fourth electrode through via holes formed in the first insulating layer, the buffer layer, the first gate insulating layer and the second gate insulating layer; the fourth electrode is electrically coupled to the third electrode through a via hole formed in the intermediate dielectric layer;
the data line extending from the area where the connection unit is located to the area where the display unit is located is electrically coupled to the fifth electrode through via holes formed in the first insulating layer, the buffer layer and the first gate insulating layer, and the fifth electrode is electrically coupled to the third electrode through via holes formed in the second gate insulating layer and the intermediate dielectric layer.

In some implementations, the driving circuit further includes a sixth electrode disposed between the first gate insulating layer and the second gate insulating layer, and the sixth electrode and the first gate electrode are made of a same material and are electrically coupled to each other;
the conductive connecting part further includes the scan line which includes a first scan line, and the first scan line extending from the area where the connection unit is located to the area where the display unit is located is electrically coupled to the sixth electrode through via holes formed in the first insulating layer, the buffer layer and the first gate insulating layer.

In some implementations, the driving circuit further includes a seventh electrode disposed between the second gate insulating layer and the intermediate dielectric layer, and the seventh electrode and the second gate electrode are made of a same material and are electrically coupled to each other;
the scan line further includes a second scan line, and the second scan line extending from the area where the connection unit is located to the area where the display unit is located is electrically coupled to the seventh electrode through via holes formed in the first insulating layer, the buffer layer, the first gate insulating layer and the second gate insulating layer.

In some implementations, the first insulating part further includes a pixel defining layer and a protective layer, the pixel defining layer and the protective layer are disposed on a side of the planarization layer away from the base substrate, and the pixel defining layer and the protective layer are stacked sequentially in a direction away from the base substrate;
the pixel defining layer is configured to define an arrangement position of the light emitting element;
the second insulating part further includes a third insulating layer, the third insulating layer is arranged on a side of the second insulating layer away from the base substrate, and the third insulating layer and the protective layer are made of a same material.

In some implementations, a surface of the first insulating part on a side thereof away from the base substrate is substantially flush with a surface of the second insulating part on a side thereof away from the base substrate.

In some implementations, the first insulating part is adjacent to the second insulating part, and an acute included angle between an adjacent surface of the first insulating part and the second insulating part and the base substrate is greater than or equal to 45° and less than 90°.

In some implementations, a plurality of display units arranged in an array are arranged on the base substrate, and the connection unit is configured to connect adjacent ones of the display units along a row direction and a column direction of the array;
the hollowed-out unit is arranged between the display unit and the connection unit; the base substrate includes a first sub-layer and a second sub-layer stacked on each other, and the second sub-layer is closer to the display unit and the connection unit than the first sub-layer;
the hollowed-out unit includes hollowed-out patterns arranged in the second sub-layer and in film layers on the second sub-layer, and orthographic projections of the hollowed-out patterns, in the second sub-layer and in the film layers on the second sub-layer, on the first sub-layer are at least partially overlapped.

In some implementations, the display device further includes an encapsulation layer, the encapsulation layer is arranged on a side of the display unit and the connection unit away from the base substrate, and the encapsulation layer encapsulates the display unit and the connection unit;
a part of the encapsulation layer, which encapsulates the display unit, is a first part, and a part of the encapsulation layer, which encapsulates the connection unit, is a second part;
the first part has a thickness greater than that of the second part.

In some implementations, in the display unit, an orthographic projection of the intermediate dielectric layer on the base substrate covers an entire area where the display unit is located;
a part of an orthographic projection of the planarization layer on the base substrate is not overlapped with the orthographic projection of the intermediate dielectric layer on the base substrate, a plurality of grooves are formed in the intermediate dielectric layer at a side thereof away from the base substrate, and the grooves are located in an area, an orthographic projection of which is not overlapped with the orthographic projection of the planarization layer on the base substrate, of the intermediate dielectric layer;
parts of the protective layer and the encapsulation layer corresponding to the grooves are embedded in the grooves.

In some implementations, the conductive connecting part is made of any one of Ti, Al, Mo, Ag, ITO, IZO, ZnO, In₂O₃, IGO, AZO, rubber mixed with conductive particles, and carbon nanotubes.

In some implementations, the second insulating layer is made of any one of a general-purpose polymer of polymethylmethacrylate and polystyrene, a phenol group-based polymer derivative, an acryl-based polymer, a p-xylene-based polymer, an arylene ether-based polymer, an amide-based polymer, a fluoride-based polymer, a vinyl alcohol-based polymer, or a mixture of two or more thereof.

In some implementations, the first sub-layer and the second sub-layer each are made of any one of dimethylsiloxane, polyimide, and PET (polyethylene terephthalate).

In some implementations, the first insulating layer, the buffer layer, the first gate insulating layer, the second gate insulating layer, the intermediate dielectric layer and the protective layer each are formed by a single-layer structure layer made of any one of SiOx, SiONx and SiNx; or,
the first insulating layer, the buffer layer, the first gate insulating layer, the second gate insulating layer, the intermediate dielectric layer and the protective layer each are formed by a multilayer structure layer made of more than two materials of SiOx, SiONx and SiNx.

In some implementations, the encapsulation layer is made of an inorganic material, an organic material, or a combination of an inorganic material and an organic material;
the inorganic material includes any one or more of SiOx, SiONx, SiNx, aluminum oxide, aluminum nitride, titanium oxide and titanium nitride;
the organic material includes any one or more of polymethacrylate, polycarbonate, acrylic resin and epoxy resin.

In a second aspect, an embodiment of the present disclosure provides a display panel including the display substrate described above.

In a third aspect, an embodiment of the present disclosure provides a display device including the display panel described above.

### BRIEF DESCRIPTION OF DRAWINGS

The accompanying drawings are included to provide a further understanding of the embodiments of the present disclosure, and are incorporated in and constitute a part of this specification, illustrate embodiments of the present disclosure and together with the description serve to explain the principles of the present disclosure, but do not limit the present disclosure. The above and other features and advantages will become more apparent to those skilled in the art by describing in detail exemplary embodiments thereof with reference to the attached drawings, in which:

FIG. 1 is a schematic cross-sectional view of a connection wiring part of a stretchable display device;

FIG. 2 is a schematic cross-sectional view of a connection wiring part of a stretchable display device;

FIG. 3 is a schematic top view of a display substrate according to an embodiment of the present disclosure;

FIG. 4 is an enlarged top view of a part A of the display substrate shown in FIG. 3;

FIG. 5 is a schematic cross-sectional view of the display substrate shown in FIG. 4 taken along line BB;

FIG. 6 is a schematic structural diagram illustrating step S1 of a method for manufacturing the display substrate shown in FIG. 5;

FIG. 7 is a schematic structural diagram illustrating step S2 of a method for manufacturing the display substrate shown in FIG. 5;

FIG. 8 is a schematic structural diagram illustrating step S3 of a method for manufacturing the display substrate shown in FIG. 5;

FIG. 9 is a schematic structural diagram illustrating step S4 of a method for manufacturing the display substrate shown in FIG. 5;

FIG. 10 is a schematic structural diagram illustrating step S5 of a method for manufacturing the display substrate shown in FIG. 5;

FIG. 11 is a schematic structural diagram illustrating step S6 of a method for manufacturing the display substrate shown in FIG. 5;

FIG. 12 is a schematic structural diagram illustrating step S7 of a method for manufacturing the display substrate shown in FIG. 5;

FIG. 13 is a schematic structural diagram illustrating step S8 of a method for manufacturing the display substrate shown in FIG. 5;

FIG. 14 is a schematic structural diagram illustrating step S9 of a method for manufacturing the display substrate shown in FIG. 5;

FIG. 15 is a schematic structural diagram illustrating step S10 of a method for manufacturing the display substrate shown in FIG. 5;

FIG. 16 is a schematic structural diagram illustrating step S11 of a method for manufacturing the display substrate shown in FIG. 5;

FIG. 17 is a schematic structural diagram illustrating step S12 of a method for manufacturing the display substrate shown in FIG. 5;

FIG. 18 is a schematic structural diagram illustrating step S13 of a method for manufacturing the display substrate shown in FIG. 5;

FIG. 19 is a schematic structural diagram illustrating step S14 of a method for manufacturing the display substrate shown in FIG. 5;

FIG. 20 is a schematic structural diagram illustrating step S15 of a method for manufacturing the display substrate shown in FIG. 5;

FIG. 21 is a schematic structural diagram illustrating step S16 of a method for manufacturing the display substrate shown in FIG. 5;

FIG. 22 is a schematic structural diagram illustrating step S17 of the method for preparing the substrate shown in FIG. 5;

FIG. 23 is a schematic structural diagram illustrating step S18 of a method for manufacturing the display substrate shown in FIG. 5;

FIG. 24 is a schematic cross-sectional view of the display substrate shown in FIG. 4 taken along line BB;

FIG. 25 is a schematic cross-sectional view of the display substrate shown in FIG. 4 taken along line BB;

FIG. 26 is a schematic cross-sectional view of the display substrate shown in FIG. 4 taken along line BB;

FIG. 27 is a schematic cross-sectional view of the display substrate shown in FIG. 4 taken along line BB; and

FIG. 28 is a schematic cross-sectional view of the display substrate shown in FIG. 4 taken along line BB.

### REFERENCE NUMBERS ARE AS FOLLOWS

1. base substrate; 11. first sub-layer; 12. second sub-layer; 13. adhesive layer; 2. display unit; 3. connection unit; 4. hollowed-out unit; 220. driving circuit; 221. light emitting element; 31. second insulating part; 32. conductive connecting part; 101. first gate electrode; 102. second gate electrode; 103. active layer; 104. source electrode; 105. drain electrode; 106. first electrode; 107. light emitting functional layer; 108. second electrode; 109. power supply signal electrode; 110. third electrode; 111. fourth electrode; 112. fifth electrode; 113. sixth electrode; 114. seventh electrode; 200. groove; 201. first insulating layer; 202. buffer layer; 203. first gate insulating layer; 204. second gate insulating layer; 205. intermediate dielectric layer; 206. planarization layer; 207. support spacer; 208. pixel defining layer; 209. protective layer; 301. second insulating layer; 302. third insulating layer; 5. encapsulation layer; 51. inorganic material encapsulation layer; 52. organic material encapsulation layer; 12′, second sub-layer film; 201′, first insulating layer film; 202′, buffer layer film; 6. glass substrate; 203′, first gate insulating layer film; 204′, second gate insulating layer film; 205′, intermediate dielectric layer film; 51′, inorganic material encapsulation layer film; 7. connection wiring part; 8. flexible substrate; 9. area where connection wiring is located; 10. display area; 14. insulating layer; 15. hollowed-out area; 16. elastic material layer.

### DETAIL DESCRIPTION OF EMBODIMENTS

In order to make those skilled in the art better understand the technical solutions of the embodiments of the present disclosure, the following describes a display substrate, a display panel and a display device provided in the embodiments of the present disclosure in further detail with reference to the accompanying drawings and the detailed description.

The embodiments of the present disclosure will be described more fully hereinafter with reference to the accompanying drawings, but the embodiments shown may be embodied in different forms and should not be construed as limited to the embodiments set forth herein. Rather, these embodiments are provided so that the present disclosure will be more thorough and complete, and will fully convey the scope of the present disclosure to those skilled in the art.

The embodiments of the present disclosure are not limited to the embodiments shown in the drawings, but include modifications of configurations formed based on a manufacturing process. Thus, areas illustrated in the figures have schematic properties, and shapes of the areas shown in the figures illustrate specific shapes of the areas, but are not intended to be limiting.

In the related art, in order to realize a stretchable flexible display device, a hollowed-out part is arranged in a substrate of a flexible display device, and the hollowed-out part can release a strain capacity of the flexible display device during the flexible display device being stretched, which is an effective method for manufacturing the stretchable flexible display device. However, for the stretchable flexible display device with the hollowed-out part disposed in the substrate thereof, a tensile stress strain during a stretching process is mainly concentrated on a connection wiring part (i.e., conductive connection wiring part on the substrate, such as metal wire), and thus, how to effectively ensure that the metal wire of the connection wiring part will not be broken during the stretching process is a problem to be solved urgently.

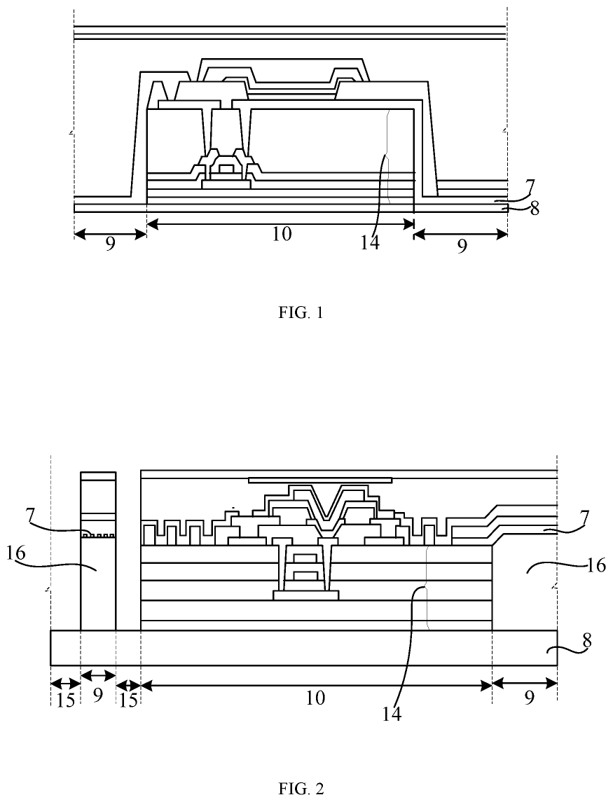

In the related art, as shown in FIG. 1, in a the stretchable display device, a connection wiring part 7 is directly formed on a flexible substrate 8, for example, a metal wire is directly deposited on the flexible substrate 8, and an insulating layer 14 (including an inorganic insulating layer and an organic insulating layer that are stacked on each other) above the connection wiring part 7 is etched and removed, the connection wiring part 7 needs to be introduced into a display area 10 from an area 9 where a connection wiring is located and electrically coupled to a conductive structure therein, so as to introduce a signal to the conductive structure in the display area 10 through the connection wiring part 7, thereby realizing the display of the display area 10. In such design, the connection wiring part 7 needs to pass a high step formed by etching and removing the insulating layer 14 so as to be introduced into the display area 10 and electrically coupled to the conductive structure in the display area 10, and thus the connection wiring part 7 is prone to be broken when climbing the high step; meanwhile, the high step is located right on a boundary between the area 9 where the connection wiring is located and the display area 10, and the boundary is subjected to a larger tensile stress in a stretching process of stretching the stretchable display device, so that a portion of the connection wiring part 7 at the high step is prone to be broken when the stretchable display device is stretched, and the display quality of the stretchable display device is seriously affected.

In addition, in the related art, as shown in FIG. 2, a hollowed-out area 15 is disposed in a flexible display device, and a connection wiring part 7 is disposed at a conventional position, for example, the connection wiring part 7 and a conductive structure, coupled thereto, in the display area 10 are disposed in a same layer, an insulating layer 14 in an area 9 where a connection wiring is located is etched and removed, and an area where the inorganic insulating layer is removed is filled with an elastic material layer 16 (such as an organic resin material layer) to protect the metal wire from being broken, but such process is relatively complicated, and the risk of breaking the metal wire during stretching is also relatively high.

In order to solve at least the problem that a connection wiring part of a stretchable display device is prone to be broken in a stretching process, the embodiments of the present disclosure provide a display substrate, a display panel and a display device.

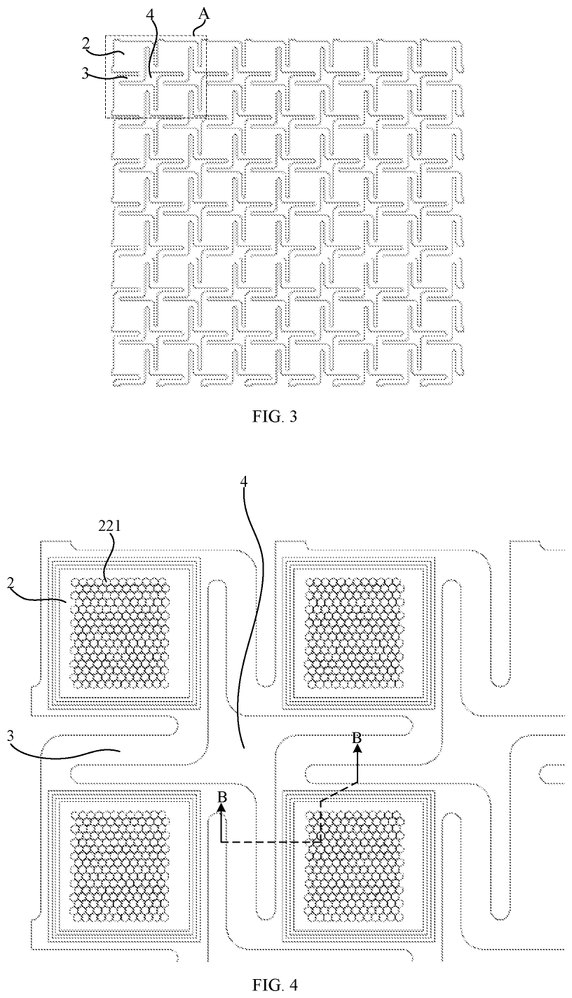

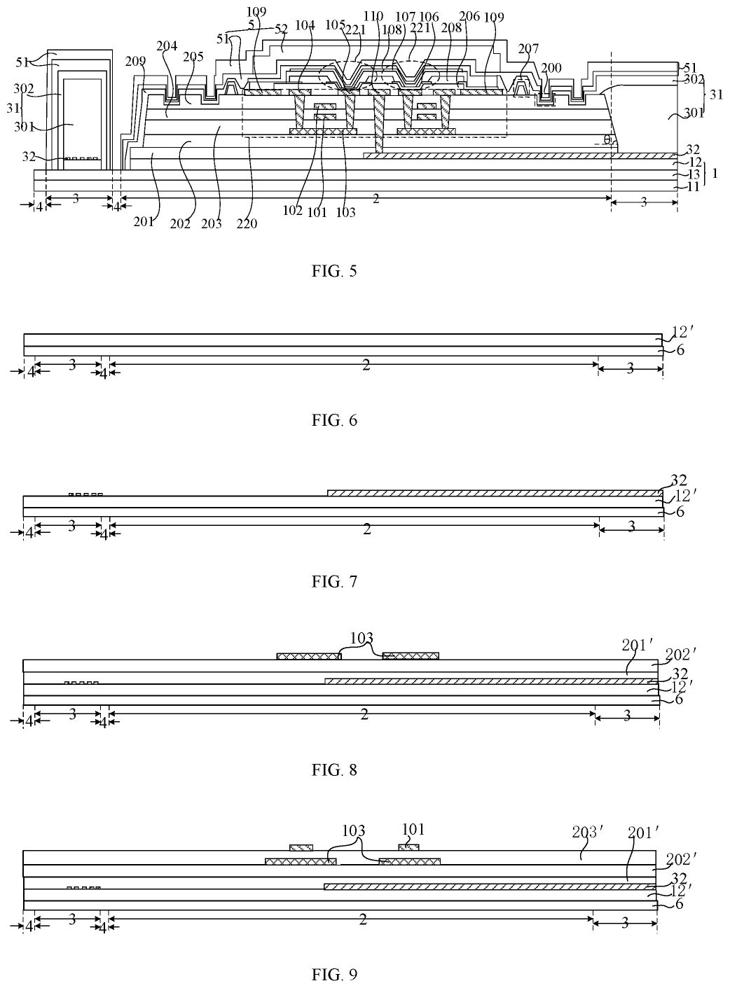

An embodiment of the present disclosure provides a display substrate, as shown in FIGS. 3 to 5, the display substrate includes a base substrate 1, and a display unit 2, a connection unit 3, and a hollowed-out unit 4 which are disposed on the base substrate 1, where the display unit 2, the connection unit 3, and the hollowed-out unit 4 are adjacent to each other; the display unit 2 includes a first insulating part and a conductive part; the connection unit 3 includes a second insulating part 31 and a conductive connecting part 32, where the second insulating part 31 is arranged on a side of the conductive connecting part 32 away from the base substrate 1; the conductive connecting part 32 is in contact with the base substrate 1, extends from an area of the base substrate 1 where the connection unit 3 is located to an area where the display unit 2 is located, and is electrically coupled to the conductive part through a via hole formed in the first insulating part; the second insulating part 31 has a tensile property superior to that of the first insulating part. In some implementations, other film layers may be disposed between the conductive connecting part 32 and the base substrate 1. The display substrate is stretchable. The base substrate 1 has a good tensile property. The connection unit 3 has a certain tensile property. The display unit 2 has substantially no tensile property. The display unit 2 refers to a pixel structure part for display in the display substrate. The connection unit 3 refers to a signal wiring part for supplying various signals to the pixel structure part in the display substrate. The hollowed-out unit 4 refers to a portion of the display substrate where no film layer is disposed, and the hollowed-out unit 4 is formed by hollowed-out patterns disposed in film layers in the display substrate. When the display substrate is stretched, the display unit 2 substantially cannot be stretched, and the display unit 2 is substantially not influenced by a stress of stretching; the connection unit 3 and the hollowed-out unit 4 can be stretched, and the connection unit 3 and the hollowed-out unit 4 are used for releasing a tensile stress generated when the display substrate is stretched.

By providing the hollowed-out unit 4 on the base substrate 1, most of tensile stress of the display substrate during stretching can be released; by enabling the conductive connecting part 32 to be in contact with the base substrate 1 and to extend from the area of the base substrate 1 where the connection unit 3 is located to the area of the base substrate 1 where the display unit 2 is located so as to be electrically coupled to the conductive part through the via hole formed in the first insulating part, compared with the design of the connection wiring part shown in FIG. 1 in the related art, the conductive connecting part 32 can be electrically coupled to the conductive part without climbing a high step formed by the first insulating part, a situation that the conductive connecting part 32 is prone to be broken when climbing the high step is improved or avoided, and meanwhile, since the display unit 2 is substantially not influenced by the tensile stress, the via hole formed in the display unit 2 is also substantially not influenced by the tensile stress in the process of stretching the display substrate, so that a situation that the conductive connecting part 32 is prone to be pulled apart when the display substrate is stretched can also be improved or avoided; by making the tensile property of the second insulating part 31 better than that of the first insulating part, the second insulating part 31 with a better tensile property can form good protection for the conductive connecting part 32, thereby further improving the tensile property of the connection unit 3 and improving or avoiding the situation that the conductive connecting part 32 is prone to be broken by the tensile stress when the display substrate is stretched.

In addition, compared with the design of the connection wiring part in FIG. 2 in the related art, by providing the conductive connecting part 32 on the base substrate 1 and making the conductive connecting part 32 directly in contact with the base substrate 1, when the base substrate 1 has a good tensile property, the conductive connecting part 32 with a certain tensile property can be strained correspondingly along with the tensile strain of the base substrate 1 when the display substrate is stretched, and by contrast, in the case that another insulating film layer is further disposed between the connection wiring part and the base substrate in FIG. 2, since the another insulating film layer is also subjected to a tensile force and need to release the tensile force applied thereto when the display substrate is stretched, the conductive connecting part 32 inevitably needs to bear the stress released by the another insulating film layer, so that the conductive connecting part 32 finally bears a larger superimposed tensile stress, and the conductive connecting part 32 is prone to be broken due to the fact that the conductive connecting part 32 cannot bear too large tensile stress, therefore, the display substrate provided in the embodiment of the present disclosure can better improve the tensile property of the connection unit 3, and better improve or avoid the situation that the conductive connecting part 32 is prone to be broken by the tensile stress when the display substrate is stretched.

In some implementations, the conductive part includes a driving circuit 220 and a light emitting element 221, the light emitting element 221 is located on a side of the driving circuit 220 away from the base substrate 1; the driving circuit 220 is electrically coupled to the light emitting element 221, and is configured to drive the light emitting element 221 to emit light; the conductive connecting part 32 includes at least one of a data line, a scan line, a power supply signal line, and a control signal line; the data line, the scan line, the power supply signal line and the control signal line are electrically coupled to the driving circuit 220, respectively; the data line is configured to provide a data signal for driving the light emitting element 221 to emit light; the scan line is configured to provide a scan signal for driving the light emitting element 221 to emit light; the power supply signal line is configured to provide a power supply signal for driving the light emitting element 221 to emit light; the control signal line is configured to provide a control signal for driving the light emitting element 221 to emit light.

The conductive connecting part 32 in FIG. 3 and FIG. 4 is a cluster of signal wirings including multiple signal lines, and does not indicate any one or a single one of the signal wirings. For example, scan lines, e.g., gate lines, are configured to perform scan driving on an array of light emitting elements 221 row by row to display a frame of picture. Various control signal lines, such as an enable signal line, a clock signal line, a reset signal line and a compensation signal line, may be used in the driving circuit 220. In some implementations, the conductive part is located in the display area, and the conductive connecting part 32 is located in a wiring area between portions of the conductive part, the wiring area is a non-display area. In some implementations, the light emitting element 221 may be an organic electroluminescent element, or may be any other light emitting element such as a light emitting diode, a micro LED, or the like.

In some implementations, the driving circuit 220 includes a driving transistor including a first gate electrode 101, a second gate electrode 102, an active layer 103, a source electrode 104, and a drain electrode 105; orthographic projections of the first gate electrode 101 and the second gate electrode 102 on the base substrate 1 each are within an orthographic projection of the active layer 103 on the base substrate 1; orthographic projections of the source electrode 104 and the drain electrode 105 on the base substrate 1 are respectively positioned at two opposite ends of the orthographic projection of the active layer 103 on the base substrate 1; the first insulating part includes a first insulating layer 201, a buffer layer 202, a first gate insulating layer 203, a second gate insulating layer 204, an intermediate dielectric layer 205 and a planarization layer 206 which are stacked sequentially in a direction away from the base substrate 1; the active layer 103 is positioned between the buffer layer 202 and the first gate insulating layer 203; the first gate electrode 101 is located between the first gate insulating layer 203 and the second gate insulating layer 204; the second gate electrode 102 is located between the second gate insulating layer 204 and the intermediate dielectric layer 205; the source electrode 104 and the drain electrode 105 are located between the intermediate dielectric layer 205 and the planarization layer 206; the light emitting element 221 is disposed on a side of the planarization layer 206 away from the base substrate 1, and the light emitting element 221 includes a first electrode 106, a light emitting functional layer 107, and a second electrode 108 which are stacked sequentially; the drain electrode 105 is electrically coupled to the first electrode 106 through a via hole formed in the planarization layer 206.

In some implementations, the driving transistor may be provided with only one gate electrode, i.e., may be a single-gate driving transistor, and the driving for the light emitting element 221 can also be achieved.

The light emitting element 221 is an organic electroluminescence element. The first electrode 106 is an anode of the light emitting element 221, and the second electrode 108 is a cathode of the light emitting element 221. The planarization layer 206 can planarize a side of the intermediate dielectric layer 205 away from the base substrate 1, thereby facilitating a formation of the light emitting element 221 on a planarized surface of the planarization layer 206. A power supply signal electrode 109 is further formed in the same layer and made of the same material as the source electrode 104 and the drain electrode 105. A support spacer 207 is further formed in the same layer and made of the same material as the planarization layer 206. The support spacer 207 can form a support for the encapsulation layer 5 for encapsulating the light emitting element 221.

In some implementations, the first gate electrode 101, the second gate electrode 102, the source electrode 104, and the drain electrode 105 are made of any one of Ti, Al, Mo, Ag, ITO, IZO, ZnO, In₂O₃, IGO, AZO, rubber mixed with conductive particles, and carbon nanotubes. The active layer 103 is made of an inorganic semiconductor material (e.g., amorphous silicon or polysilicon material), an organic semiconductor material, or an oxide-containing semiconductor material (e.g., a semiconductor material containing an oxide of Zn, In, Ga, or the like). The first insulating layer 201, the buffer layer 202, the first gate insulating layer 203, the second gate insulating layer 204 and the intermediate dielectric layer 205 each are formed by a single-layer structure layer made of any one of SiOx, SiONx and SiNx, or, a multilayer structure layer made of more than two materials of SiOx, SiONx and SiNx. The planarization layer 206 is made of any one of a general-purpose polymer of polymethylmethacrylate and polystyrene, a phenol group-based polymer derivative, an acryl-based polymer, a p-xylene-based polymer, an arylene ether-based polymer, an amide-based polymer, a fluoride-based polymer, and a vinyl alcohol-based polymer, or a mixture of two or more thereof. The first electrode 106 and the second electrode 108 each are made of a conductive metal such as Ti, Al, Mo, Ag, or a conductive metal oxide material such as ITO, IZO, ZnO, In₂O₃, IGO, AZO, or the like. The light emitting functional layer 107 is made of a phosphorescent light emitting material or a fluorescent light emitting material.

In some implementations, the conductive connecting part 32 extending from the area where the connection unit 3 is located to the area where the display unit 2 is located is located between the first insulating layer 201 and the base substrate 1; the second insulating part 31 includes a second insulating layer 301, and the second insulating layer 301 and the planarization layer 206 are made of a same material. The second insulating layer 301 is made of any one of a general-purpose polymer of polymethylmethacrylate and polystyrene, a phenol group-based polymer derivative, an acryl-based polymer, a p-xylene-based polymer, an arylene ether-based polymer, an amide-based polymer, a fluoride-based polymer, and a vinyl alcohol-based polymer, or a mixture of two or more thereof. The second insulating layer 301 has a good tensile property, so that it can protect the conductive connecting part 32 well, and the conductive connecting part 32 is not prone to be broken when being stretched along with the base substrate 1.

In some implementations, the conductive connecting part 32 is made of any one of Ti, Al, Mo, Ag, ITO, IZO, ZnO, In₂O₃, IGO, AZO, rubber mixed with conductive particles, and carbon nanotubes. The conductive connecting part 32 made of the material as above has a better tensile property, can correspondingly generate a tensile deformation along with the stretching of the base substrate 1 when the display substrate is stretched, and can improve or avoid the condition that the conductive connecting part 32 is prone to be broken.

In some implementations, the driving circuit 220 further includes a third electrode 110, the third electrode 110 is disposed between the intermediate dielectric layer 205 and the planarization layer 206, and the third electrode 110 is electrically coupled to the drain electrode 105; the conductive connecting part 32 includes a data line, and the data line extending from the area where the connection unit 3 is located to the area where the display unit 2 is located is electrically coupled to the third electrode 110 through via holes formed in the first insulating layer 201, the buffer layer 202, the first gate insulating layer 203, the second gate insulating layer 204, and the intermediate dielectric layer 205.

For forming the third electrode 110, a film layer of a material of the third electrode can be deposited in via holes (e.g., on side walls of the via holes and bottoms of the via holes) formed in the first insulating layer 201, the buffer layer 202, the first gate insulating layer 203, the second gate insulating layer 204, and the intermediate dielectric layer 205 by a film forming process (e.g., a sputtering film formation process or a plasma enhanced chemical vapor deposition process) when forming a film layer of the third electrode, thereby achieving an electrical connection between the data line and the third electrode 110 through the via holes. In addition, since the display unit 2 is not stretchable and is not substantially affected by the tensile stress, the via hole formed in the display unit 2 is not substantially affected by the tensile stress during the stretching of the display substrate, so that a reliable electrical connection between the data line and the third electrode 110 can be ensured through the conductive material film layer in the via hole, and the display quality of the display substrate can be ensured.

In some implementations, the first insulating part further includes a pixel defining layer 208 and a protective layer 209, the pixel defining layer 208 and the protective layer 209 are disposed on a side of the planarization layer 206 away from the base substrate 1, and the pixel defining layer 208 and the protective layer 209 are stacked sequentially in a direction away from the base substrate 1; the pixel defining layer 208 is configured to define an arrangement position of the light emitting element 221; the second insulating part 31 further includes a third insulating layer 302, the third insulating layer 302 is disposed on a side of the second insulating layer 301 away from the base substrate 1, and the third insulating layer 302 and the protective layer 209 are made of a same material. The pixel defining layer 208 further extends to cover the support spacer 207.

In some implementations, the pixel defining layer 208 is made of any one of a general-purpose polymer of polymethyl methacrylate and polystyrene, a phenol group-based polymer derivative, an acryl-based polymer, a p-xylene-based polymer, an arylene ether-based polymer, an amide-based polymer, a fluoride-based polymer, and a vinyl alcohol-based polymer or a mixture of two or more thereof. The protective layer 209 is formed by a single-layer structure layer made of any one of SiOx, SiONx and SiNx; or, a multilayer structure layer made of more than two materials of SiOx, SiONx and SiNx.

During manufacturing the display substrate, after the pixel defining layer 208 is formed on the base substrate 1, a hollowed-out part needs to be formed in the flexible base substrate 1, since the flexible base substrate 1 is made of an organic material which is the same as or similar to that of the pixel defining layer 208, and when the hollowed-out part is formed in the flexible base substrate 1 by dry etching, etching damage is inevitably caused to the pixel defining layer 208 made of the same or similar material as the flexible base substrate 1, and thus by forming the protective layer 209 made of an inorganic insulating material on the side of the pixel defining layer 208 away from the base substrate 1, the pixel defining layer 208 and the film layer, which is made of the same or similar material as the pixel defining layer 208 and exposed to the outside, can be prevented from being etched and damaged when the hollowed-out part is formed in the flexible base substrate 1, and the quality of the display substrate is ensured. In addition, since the second insulating layer 301 is made of the same or similar material as the pixel defining layer 208, the third insulating layer 302 can well protect the second insulating layer 301 from being etched and damaged when the hollowed-out part is formed in the flexible base substrate 1.

In some implementations, a surface of the first insulating part on a side thereof away from the base substrate 1 is substantially flush with a surface of the second insulating part 31 on a side thereof away from the base substrate 1. With such an arrangement, on one hand, it can be ensured that an entire surface of the display substrate on a side thereof where the light emitting element 221 is arranged tends to be flat, so that it can be ensured that the subsequent encapsulation layer 5 can form a good encapsulation for the light emitting element 221; on the other hand, a phenomenon that the display substrate is locally broken or pulled apart due to an excessive thickness difference between the display unit 2 and the connection unit 3 when the display substrate is stretched can be avoided, and the quality of the display substrate can be ensured.

In some implementations, the first insulating part is adjacent to the second insulating part 31, and an acute included angle θ between an adjacent surface of the first insulating part and the second insulating part 31 and the base substrate 1 is greater than or equal to 45° and less than 90°. The display unit 2 is adjacent to the connection unit 3, which is structurally mainly embodied in that the first insulating part and the second insulating part 31 are adjacent to each other, and the adjacent surface of the first insulating part and the second insulating part 31 is an inclined plane with an acute included angle θ greater than or equal to 45° and less than 90° with respect to the base substrate 1. With such an arrangement, when the display substrate is stretched, since orthographic projections of interfaces of film layers in the first insulating part and film layers in the second insulating part 31 on the base substrate 1 are not located at a same position, the distribution of the tensile stress borne by the interfaces of the film layers in the first insulating part and the film layers in the second insulating part 31 is relatively dispersed, so that the possibility that the first insulating part and the second insulating part 31 are separated from each other under the action of tensile stress can be reduced, the conductive connecting part 32 protected by the second insulating part 31 is not prone to be broken or pulled apart, and the tensile property of the display substrate is greatly improved.

In some implementations, a plurality of display units 2 are disposed on the base substrate 1, the plurality of display units 2 are arranged in an array, and the connection unit 3 is configured to connect adjacent ones of the display units 2 along a row direction and a column direction of the array; the hollowed-out unit 4 is arranged between the display unit 2 and the connection unit 3; the base substrate 1 includes a first sub-layer 11 and a second sub-layer 12 stacked on top of each other, the second sub-layer 12 is closer to the display unit 2 and the connection unit 3 than the first sub-layer 11; the hollowed-out unit 4 includes hollowed-out patterns disposed in the second sub-layer 12 and in film layers on the second sub-layer 12, and orthographic projections of the hollowed-out patterns in the second sub-layer 12 and in the film layers on the second sub-layer 12 on the first sub-layer 11 are at least partially overlapped. That is, the hollowed-out unit 4 penetrates all layers of the display substrate except the first sub-layer 11.

In some implementations, hollowed-out units 4 are regularly distributed in a spacing area between the display units 2 arranged in the array, for example, an orthographic projection of the hollowed-out unit 4 on the first sub-layer 11 is in a cross shape, or the orthographic projection of the hollowed-out unit 4 on the first sub-layer 11 may be in any other shape, such as a gear shape. The hollowed-out unit 4 can uniformly release most of the tensile stress applied to the display substrate during the display substrate being stretched, thereby improving or avoiding the damage of the tensile stress to an internal conductive structure of the display substrate and ensuring the conductive quality of the display substrate.

In some implementations, the first sub-layer 11 and the second sub-layer 12 each are made of any one of dimethylsiloxane, polyimide, and PET. Since the first sub-layer 11 is made of a flexible material and has an excellent tensile property, by enabling the hollowed-out unit 4 to penetrate through all the film layers except the first sub-layer 11 in the display substrate, most of the tensile stress during stretching the display substrate can be released through the hollowed-out unit 4, only a small part of the tensile stress needs to be released through the connection unit 3 and a junction of the connection unit 3 and the display unit 2, and the connection unit 3 and the junction of the connection unit 3 and the display unit 2 are structurally arranged to be capable of sufficiently meeting the requirement of releasing the remaining small part of the tensile stress, so that the tensile property of the entire display substrate is improved.

In some implementations, the first sub-layer 11 and the second sub-layer 12 are bonded together by means of an adhesive layer 13. The adhesive layer 13 is made of acrylic adhesive or silicon adhesive.

In some implementations, the display substrate further includes an encapsulation layer 5, the encapsulation layer 5 is disposed on a side of the display unit 2 and the connection unit 3 away from the base substrate 1, and the encapsulation layer 5 encapsulates the display unit 2 and the connection unit 3; a part of the encapsulation layer 5 that forms an encapsulation for the display unit 2 is a first part, and a part of the encapsulation layer 5 that forms an encapsulation for the connection unit 3 is a second part; the first part has a thickness greater than that of the second part.

In some implementations, the encapsulation layer 5 is made of an inorganic material, an organic material, or a combination of an inorganic material and an organic material; the inorganic material includes any one or more of SiOx, SiONx, SiNx, aluminum oxide, aluminum nitride, titanium oxide and titanium nitride; the organic material includes one or more of polymethacrylate, polycarbonate, acrylic resin and epoxy resin. That is, the encapsulation layer 5 may be formed by one or more inorganic material layers alone, may be formed by one or more organic material layers alone, or may be formed by one or more inorganic material layers and one or more organic material layers, which are alternately stacked. The inorganic material layer can well prevent external water and oxygen from invading and damaging the light emitting element 221, the organic material layer has a good flexibility, and can well relieve the stress generated during deposition of the inorganic material layer, and can prevent the inorganic material layer from being broken under the stress effect, meanwhile, the organic material layer can further flatten the surface of the display substrate to be encapsulated, and a good encapsulation of the light emitting element 221 can be realized.

In some implementations, an orthographic projection of an encapsulation layer 51 of inorganic material on the base substrate 1 covers the area where the display unit 2 is located and the area where the connection unit 3 is located, and an orthographic projection of an encapsulation layer 52 of organic material on the base substrate 1 covers only an area where the light emitting elements 221 are distributed.

Based on the above material arrangement of the encapsulation layer 5, the encapsulation layer 5 has a certain tensile property, which can release the tensile stress to a certain extent in the stretching process of the display substrate, but the encapsulation layer 5 cannot completely release a larger tensile stress, and even may be broken or pulled apart under the action of the larger tensile stress, in the embodiment, by making the thickness of the first part of the encapsulation layer 5 larger than that of the second part thereof, the tensile property of the second part of the encapsulation layer 5 is superior to that of the first part thereof, and in the stretching process of the display substrate, since the connection unit 3 needs to bear and release a certain tensile stress, the second part of the encapsulation layer 5 with a better tensile property can assist the connection unit 3 to release a part of the tensile stress to a certain extent, and simultaneously protect the encapsulation layer 5 from being broken or pulled apart under the action of the tensile stress, thereby ensuring good encapsulation of the stretchable display substrate by the encapsulation layer 5.

In some implementations, in the display unit 2, an orthographic projection of the intermediate dielectric layer 205 on the base substrate 1 covers an area of the entire display unit 2; a part of an orthographic projection of the planarization layer 206 on the base substrate 1 is not overlapped with the orthographic projection of the intermediate dielectric layer 205 on the base substrate 1, a plurality of grooves 200 are formed on a side of the intermediate dielectric layer 205 away from the base substrate 1, and the grooves 200 are positioned in an area of the intermediate dielectric layer 205, the orthographic projection of which on the base substrate 1 is not overlapped with the orthographic projection of the planarization layer 206 on the base substrate 1; parts of the protective layer 209 and the encapsulation layer 5 corresponding to the grooves 200 are embedded in the grooves 200. With such arrangement, the protective layer 209 and the encapsulation layer 5 can form a more stable and reliable encapsulation for the display unit 2, and prevent external water and oxygen from intruding into the light emitting element 221, thereby further ensuring a hermetic encapsulation for the display substrate.

The grooves 200 formed in the side of the intermediate dielectric layer 205 away from the base substrate 1 may further extend into the second gate insulating layer 204, and parts of the protective layer 209 and the encapsulation layer 5 corresponding to the grooves 200 are embedded in the grooves 200. With such arrangement, the protective layer 209 and the encapsulation layer 5 can further form a more stable and reliable encapsulation for the display unit 2, so as to prevent external water and oxygen from invading into the light emitting element 221, thereby further ensuring a hermetic encapsulation for the display substrate.

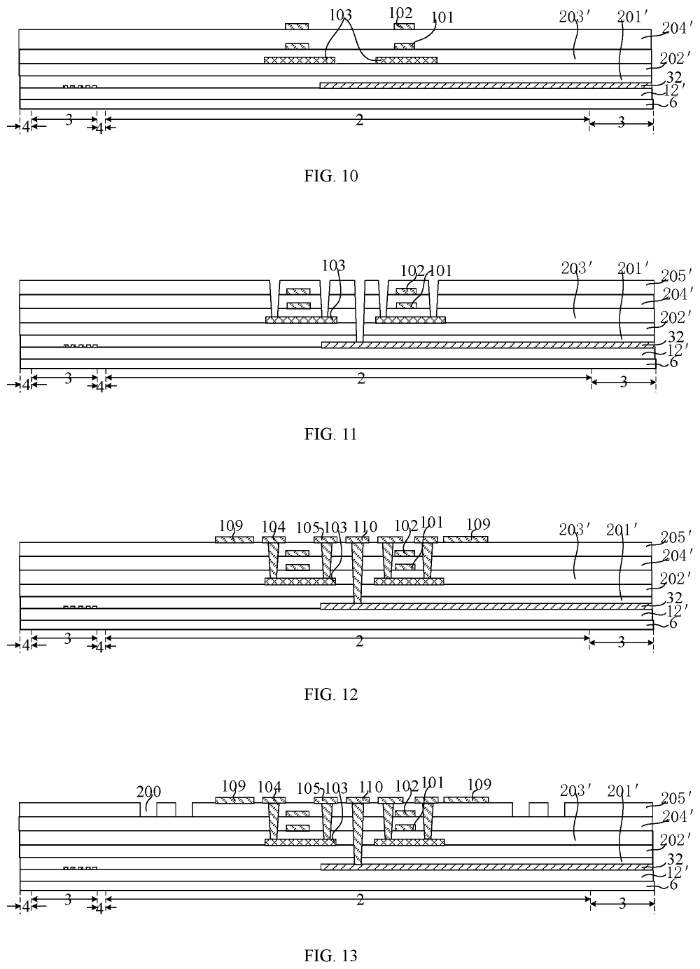

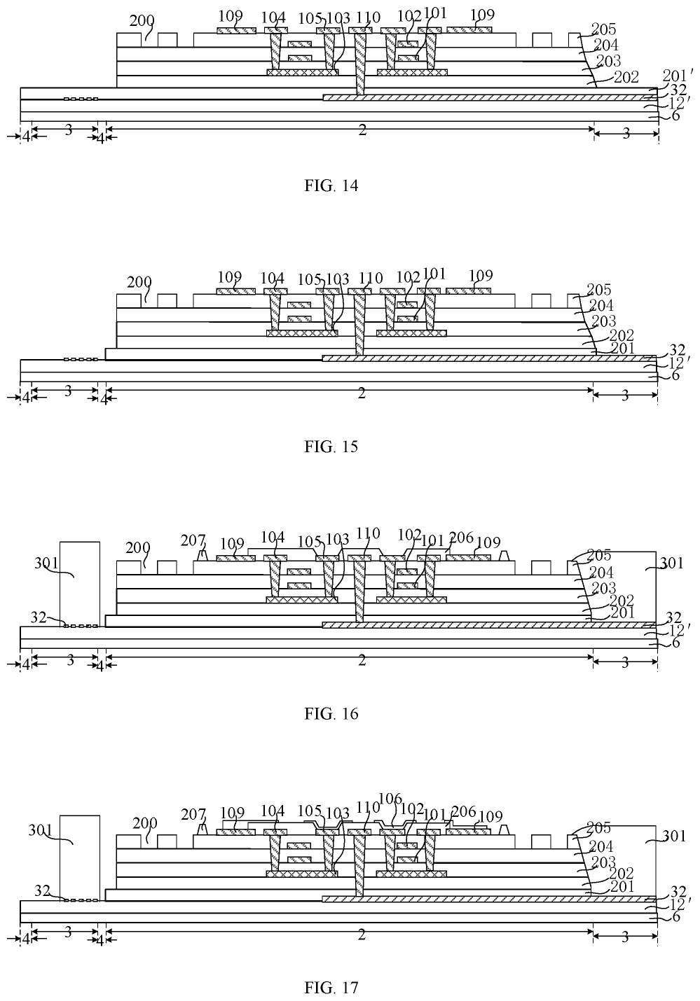

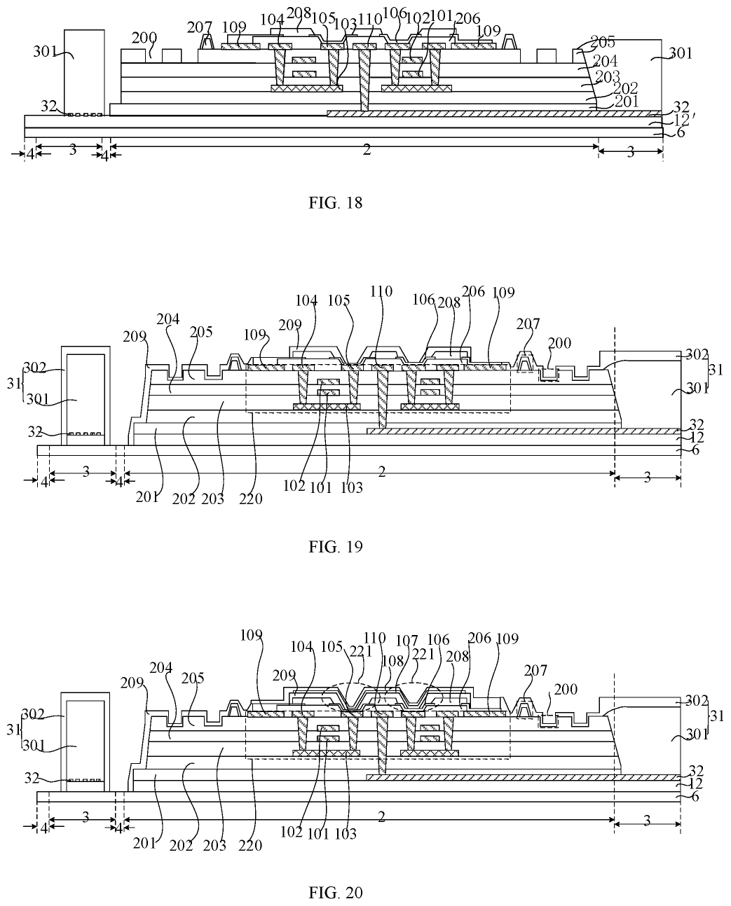

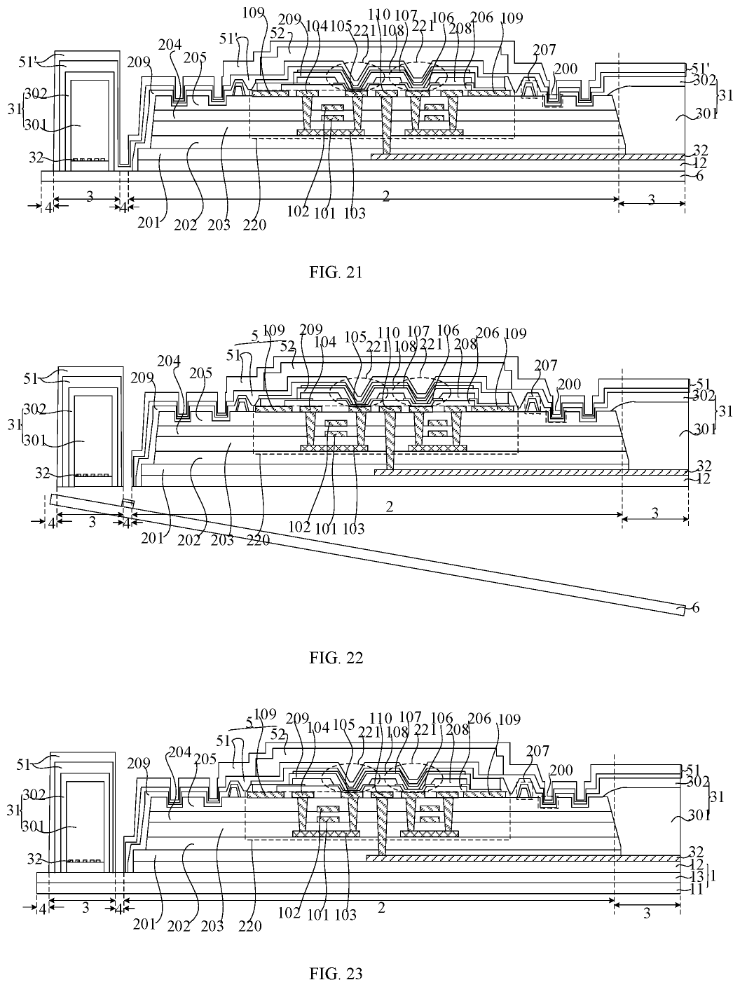

Based on the foregoing structure of the display substrate in the embodiment, a method for manufacturing the display substrate is further provided, and as shown in FIGS. 6 to 23, the method includes following steps S1 to S18.

At step S1, a second sub-layer film 12′ of the base substrate is formed on a glass substrate 6.

In this step, the second sub-layer film 12′ may be formed on the glass substrate 6 by using a printing or coating process and then cured at a certain temperature. An orthographic projection of the second sub-layer film 12′ on the glass substrate 6 covers the area where the display unit 2 is located, the area where the connection unit 3 is located and the area where the hollowed-out unit 4 is located.

At step S2, a pattern including the conductive connecting part 32 is formed on the glass substrate 6 which has been subjected to the step S1.

In this step, the pattern of the conductive connecting part 32 is formed by using a patterning process (including steps of film deposition, exposure, development, etching, and the like), and the specific process is not described any more.

At step S3, a pattern including a first insulating layer film 201′, a pattern including a buffer layer film 202′, and a pattern including the active layer 103 are sequentially formed on the glass substrate 6 which has been subjected to the step S2.

In this step, the first insulating layer film 201′ and the buffer layer film 202′ are formed by a chemical vapor deposition process, and the active layer 103 is formed by a patterning process (including steps of film deposition, exposure, development, etching, and the like), which will not be described in detail. Orthographic projections of the first insulating layer film 201′ and the buffer layer film 202′ on the glass substrate 6 cover the area where the display unit 2 is located, the area where the connection unit 3 is located, and the area where the hollowed-out unit 4 is located.

At step S4, a pattern including a first gate insulating layer film 203′ and a pattern including the first gate electrode 101 are sequentially formed on the glass substrate 6 which has been subjected to the step S3.

In this step, the first gate insulating layer film 203′ is formed by a chemical vapor deposition process, and the first gate electrode 101 is formed by a patterning process (including steps of film deposition, exposure, development, etching, and the like), which will not be described in detail. An orthographic projection of the first gate insulating layer film 203′ on the glass substrate 6 covers the area where the display unit 2 is located, the area where the connection unit 3 is located and the area where the hollowed-out unit 4 is located.

At step S5, a pattern including a second gate insulating layer film 204′ and a pattern including the second gate electrode 102 are sequentially formed on the glass substrate 6 which has been subjected to the step S4.

In this step, the second gate insulating layer film 204′ is formed by a chemical vapor deposition process, and the second gate electrode 102 is formed by a patterning process (including steps of film deposition, exposure, development, etching, and the like), which will not be described in detail herein. An orthographic projection of the second gate insulating layer film 204′ on the glass substrate 6 covers the area where the display unit 2 is located, the area where the connection unit 3 is located and the area where the hollowed-out unit 4 is located.

At step S6, a pattern including an intermediate dielectric layer film 205′ is formed on the glass substrate 6 which has been subjected to the step S5, and via holes are formed in the intermediate dielectric layer film 205′, the second gate insulating layer film 204′, the first gate insulating layer film 203′, the buffer layer film 202′ and the first insulating layer film 201′.

In this step, the intermediate dielectric layer film 205′ is formed by using a chemical vapor deposition process. The via holes in various insulating film layers may be formed simultaneously through one dry etching process, and the via holes with different depths may be formed by adjusting an etching time of the dry etching process or an intensity of etching light. An orthographic projection of the intermediate dielectric layer film 205′ on the glass substrate 6 covers the entire area where the display unit 2 is located, the area where the connection unit 3 is located and the area where the hollowed-out unit 4 is located.

At step S7, a pattern including the source electrode 104, the drain electrode 105, the third electrode 110, and the power supply signal electrode 109 is formed on the glass substrate 6 which has been subjected to the step S6.

In this step, patterns of the source electrode 104, the drain electrode 105, the third electrode 110, and the power supply signal electrode 109 are formed by one patterning process (including steps of film deposition, exposure, development, etching, and the like), and the detailed process is not repeated.

At step S8, a pattern including a plurality of grooves 200 is formed in the intermediate dielectric layer film 205′ on the glass substrate 6 which has been subjected to the step S7.

In this step, the plurality of grooves 200 are simultaneously formed through one dry etching process, and the grooves 200 have a same depth. In some implementations, depths of the grooves 200 may be different.

At step S9, a pattern including the intermediate dielectric layer 205, the second gate insulating layer 204, the first gate insulating layer 203, and the buffer layer 202 is formed on the glass substrate 6 which has been subjected to the step S8.

In this step, patterns of the intermediate dielectric layer 205, the second gate insulating layer 204, the first gate insulating layer 203, and the buffer layer 202 are simultaneously formed through one dry etching process. Orthographic projections of the intermediate dielectric layer 205, the second gate insulating layer 204, the first gate insulating layer 203 and the buffer layer 202 on the glass substrate 6 only cover the area where the display unit 22 is located, and these film layers are etched and removed in the area where the connection unit 3 is located and the area where the hollowed-out unit 4 is to be formed.

At step S10, a pattern including the first insulating layer 201 is formed on the glass substrate 6 which has been subjected to the step S9.

In this step, the pattern of the first insulating layer 201 is formed by a dry etching process. An orthographic projection of the first insulating layer 201 on the glass substrate 6 only covers the area where the display unit 2 is located, and the first insulating layer film is etched and removed in the area where the connection unit 3 is located and the area where the hollowed-out unit 4 is to be formed.

At step S11, a pattern including the planarization layer 206, the support spacer 207, and the second insulating layer 301 is formed on the glass substrate 6 which has been subjected to the step S10.

In this step, patterns of the planarization layer 206, the support spacer 207, and the second insulating layer 301 are simultaneously formed by one patterning process (including steps of film formation by printing or coating, dry etching, and the like). The support spacer 207 is formed on the intermediate dielectric layer 205 in the area where the display unit 2 is located, the planarization layer 206 is formed on a part of a conductive electrode structure in the area where the display unit 2 is located, and the drain electrode 105 of the driving transistor is exposed at the via hole in the planarization layer 206. The pattern of the second insulating layer 301 is formed in the area where the connection unit 3 is located.

The thickness of the second insulating layer 301 is greater than the thickness of the planarization layer 206, and the thickness of the planarization layer 206 is substantially the same as the height of the support spacer 207. Moreover, at an interface where the display unit 2 and the connection unit 3 are adjacent, end faces at edges of inorganic insulating film layers stacked on each other in the display unit 2 are in close contact with and attached to an end face at an edge of the second insulating layer 301.

At step S12, a pattern including the first electrode 106 is formed on the glass substrate 6 which has been subjected to the step S11.

In this step, the pattern of the first electrode 106 is formed by a patterning process (including steps of film deposition, exposure, development, etching, and the like), and the specific process is not described in detail.

At step S13, a pattern including the pixel defining layer 208 is formed on the glass substrate 6 which has been subjected to the step S12.

In this step, the pattern of the pixel defining layer 208 is formed by a patterning process (including steps of printing or coating to form a film, dry etching, and the like), and the detailed process is not described. The pixel defining layer 208 is formed only in the area where the display unit 2 is located.

At step S14, a pattern of the protective layer 209 is formed on the glass substrate 6 which has been subjected to the step S13, and then a pattern of the second sub-layer 12 is formed.

In this step, the pattern of the protective layer 209 is formed by a patterning process (including steps of film formation by a chemical vapor deposition (CVD) process, dry etching, and the like). An orthographic projection of the protective layer 209 on the glass substrate 6 covers an area other than the area where the hollowed-out unit 4 is located and a part of the first electrode 106.

In this step, a hollowed-out pattern in the second sub-layer film is formed by a dry etching process, so as to form the pattern of the second sub-layer 12.

At step S15, a pattern including the light emitting functional layer 107 and a pattern including the second electrode 108 are sequentially formed on the glass substrate 6 which has been subjected to the step S14.

In this step, the pattern of the light emitting functional layer 107 and the pattern of the second electrode 108 are sequentially formed by a patterning process (including steps of film formation by a sputtering deposition or plasma vapor deposition process, exposure, development, etching, and the like). Here, the light emitting functional layer 107 is electrically coupled to the first electrode 106 through an area of the protective layer 209 for exposing the first electrode 106.

At step S16, an encapsulation layer film 51′ of inorganic material, the encapsulation layer 52 of organic material, and an encapsulation layer film 51′ of inorganic material are formed sequentially on the glass substrate 6 which has been subjected to the step S15.

In this step, the encapsulation layer film 51′ of inorganic material is formed by a patterning process (including steps of film formation by a chemical vapor deposition process, dry etching, and the like), and the encapsulation layer 52 of organic material is formed by a patterning process (including steps of film formation by printing or coating, exposure, development, and the like). An orthographic projection of the encapsulation layer film 51′ of inorganic material on the glass substrate 6 covers the area where the display unit 2 is located, the area where the connection unit 3 is located and the area where the hollowed-out unit 4 is located. An orthographic projection of the encapsulation layer 52 of organic material on the glass substrate 6 covers the area where the light emitting element is located.

At step S17, the glass substrate 6 in the display substrate which has been subjected to the step S16 is peeled off.

In this step, when the glass substrate 6 is peeled off, the encapsulation layer film of inorganic material in the area where the hollowed-out unit 4 is located is peeled off together, thereby forming the pattern of the encapsulation layer 5. The encapsulation layer 5 includes the encapsulation layer 51 of inorganic material covering the area where the display unit 2 is located and the area where the connection unit 3 is located, and the encapsulation layer 52 of organic material covering the area where the light emitting element is located.

At step S18, the first sub-layer 11 is attached to the second sub-layer 12 of the display substrate, which has been subjected to the step S17, on the side thereof where the glass substrate is peeled off.

In this step, the first sub-layer 11 is attached to the second sub-layer 12 through an adhesive layer 13, such as a transparent optical adhesive or any other adhesive, and the display substrate is finally manufactured.

The film layers in the display substrate each are manufactured by a mature traditional process, which is not described herein again.

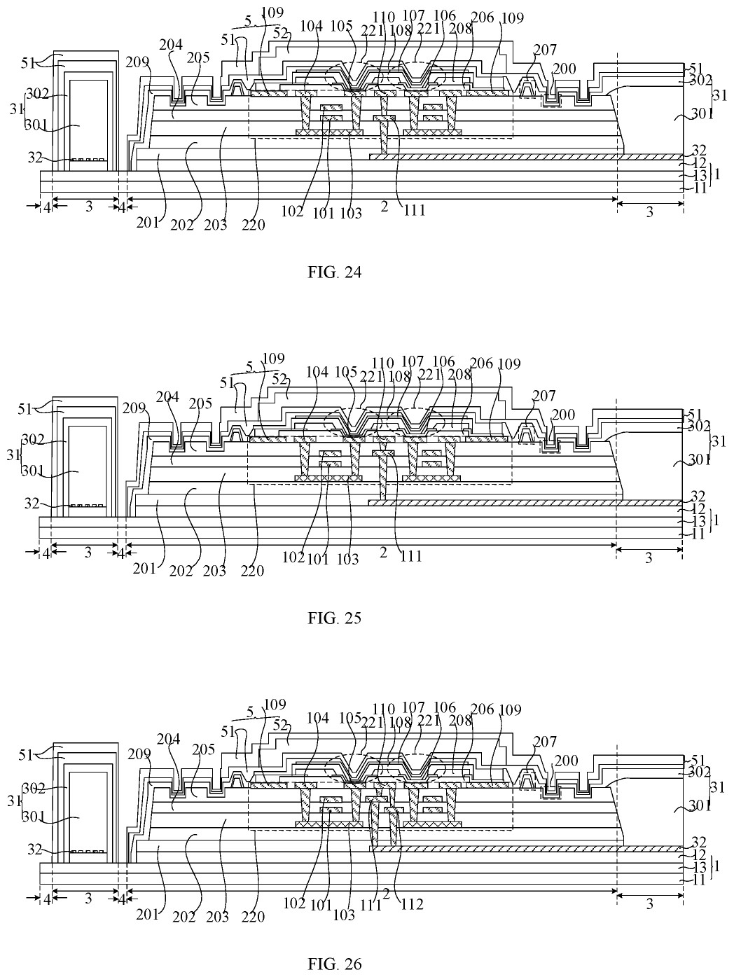

An embodiment of the present disclosure further provides a display substrate, which is different from that in the embodiment described above in that, as shown in FIG. 24, the driving circuit 220 further includes a third electrode 110 and a fourth electrode 111, the third electrode 110 is disposed between the intermediate dielectric layer 205 and the planarization layer 206, and the third electrode 110 is electrically coupled to the drain electrode 105; the fourth electrode 111 is disposed between the first gate insulating layer 203 and the second gate insulating layer 204, and the fourth electrode 111 and the first gate electrode 101 are made of a same material; the conductive connecting part 32 includes a data line, the data line extending from the area where the connection unit 3 is located to the area where the display unit 2 is located is electrically coupled to the fourth electrode 111 through a via hole formed in the first insulating layer 201, the buffer layer 202, and the first gate insulating layer 203, and the fourth electrode 111 is electrically coupled to the third electrode 110 through via holes formed in the second gate insulating layer 204 and the intermediate dielectric layer 205.

Since a plurality of insulating film layers are arranged between the third electrode 110 and the conductive connecting part 32, and an electrical connection between the third electrode 110 and the conductive connecting part 32 needs to be realized through a relatively deep via hole, as in the above embodiment, the third electrode 110 is electrically coupled to the conductive connecting part 32 through a relatively deep via hole penetrating through the insulating film layers, and under the condition that the third electrode 110 is not deposited thick enough, the phenomenon that the material of the third electrode 110 cannot be fully distributed on the sidewalls and the bottom of the relatively deep via hole penetrating through the insulating film layers easily occurs, which may cause that the material of the third electrode 110 is not deposited locally or the deposited material is relatively thin in the via hole, which easily causes the electrical connection between the third electrode 110 and the conductive connecting part 32 to be unreliable, and causes a virtual connection, so that a poor circuit connection occurs. In this embodiment, by disposing the fourth electrode 111 in the insulating layer between the third electrode 110 and the conductive connecting part 32, the fourth electrode 111 realizes a transferring for the electrical connection between the third electrode 110 and the conductive connecting part 32, and can convert an original via hole with a larger depth into two via holes with smaller depths, and in one of the two via holes, when a film layer of the third electrode 110 is deposited, a material of the third electrode 110 can be fully distributed on the sidewall and the bottom of the via hole, and the material of the third electrode 110 in the via hole is deposited relatively thick, so as to realize a reliable electrical connection between the third electrode 110 and the fourth electrode 111; in the other via hole, when a film layer of the fourth electrode 111 is deposited, a material of the fourth electrode 111 can be fully distributed on the sidewall and the bottom of the via hole, and the material of the fourth electrode 111 in the via hole is deposited relatively thick, so that a reliable electrical connection between the fourth electrode 111 and the conductive connecting part 32 is realized, and then a reliable electrical connection between the third electrode 110 and the conductive connecting part 32 is finally realized, thereby ensuring the electrical connection quality of the display substrate.

Other structures of the display substrate in this embodiment are the same as those in the above embodiment, and are not described herein again.

In the method for manufacturing the display substrate in this embodiment, only the pattern of the via hole needs to be formed when the pattern of the corresponding insulating layer is formed, and the fourth electrode needs to be simultaneously formed when the first gate is manufactured. Other steps of the method for manufacturing the display substrate are the same as those in the above embodiment, and are not described herein again.

An embodiment of the present disclosure further provides a display substrate, which is different from that in the embodiment described above in that, as shown in FIG. 25, the driving circuit 220 further includes a third electrode 110 and a fourth electrode 111, the third electrode 110 is disposed between the intermediate dielectric layer 205 and the planarization layer 206, and the third electrode 110 is electrically coupled to the drain electrode 105; the fourth electrode 111 is disposed between the second gate insulating layer 204 and the intermediate dielectric layer 205, and the fourth electrode 111 and the second gate electrode 102 are made of a same material; the conductive connecting part 32 includes a data line, the data line extending from the area where the connection unit 3 is located to the area where the display unit 2 is located is electrically coupled to the fourth electrode 111 through via holes formed in the first insulating layer 201, the buffer layer 202, the first gate insulating layer 203, and the second gate insulating layer 204, and the fourth electrode 111 is electrically coupled to the third electrode 110 through a via hole formed in the intermediate dielectric layer 205.

The principle of the display substrate in FIG. 25 to achieve a reliable electrical connection between the third electrode 110 and the conductive connecting part 32 is the same as that of the display substrate in FIG. 24.

Other structures of the display substrate in this embodiment are the same as those in the above embodiments, and are not described herein again.

In the method for manufacturing the display substrate in this embodiment, only the pattern of the via hole needs to be formed when the pattern of the corresponding insulating layer is formed, and the fourth electrode needs to be simultaneously formed when the second gate is manufactured. Other steps of the method for manufacturing the display substrate are the same as those in the above embodiments, and are not described herein again.

An embodiment of the present disclosure further provides a display substrate, which is different from that in the embodiment described above in that, as shown in FIG. 26, the driving circuit 220 further includes a third electrode 110, a fourth electrode 111, and a fifth electrode 112, the third electrode 110 is disposed between the intermediate dielectric layer 205 and the planarization layer 206, and the third electrode 110 is electrically coupled to the drain electrode 105; the fourth electrode 111 is disposed between the second gate insulating layer 204 and the intermediate dielectric layer 205, and the fourth electrode 111 and the second gate electrode 102 are made of a same material; the fifth electrode 112 is disposed between the first gate insulating layer 203 and the second gate insulating layer 204, and the fifth electrode 112 and the first gate electrode 101 are made of a same material; the conductive connecting part 32 includes a data line, the date line extending from the area where the connection unit 3 is located to the area where the display unit 2 is located is electrically coupled to the fourth electrode 111 through via holes formed in the first insulating layer 201, the buffer layer 202, the first gate insulating layer 203, and the second gate insulating layer 204; the fourth electrode 111 is electrically coupled to the third electrode 110 through a via hole formed in the intermediate dielectric layer 205; the data line extending from the area where the connection unit 3 is located to the area where the display unit 2 is located is electrically coupled to the fifth electrode 112 through via holes formed in the first insulating layer 201, the buffer layer 202, and the first gate insulating layer 203, and the fifth electrode 112 is electrically coupled to the third electrode 110 through via holes formed in the second gate insulating layer 204 and the intermediate dielectric layer 205.

That is, in this embodiment, in order to achieve a reliable electrical connection between the third electrode 110 and the conductive connecting part 32, two types of electrical connection between the third electrode 110 and the conductive connecting part 32 in FIG. 24 and FIG. 25 are combined together, so that a reliable electrical connection between the third electrode 110 and the conductive connecting part 32 can be further ensured.

Other structures of the display substrate in this embodiment are the same as those in the above embodiments, and are not described herein again.

In the method for manufacturing the display substrate in this embodiment, only the pattern of the via hole needs to be formed when the pattern of the corresponding insulating layer is formed, the fourth electrode needs to be simultaneously formed when the second gate is prepared, and the fifth electrode needs to be simultaneously formed when the first gate is prepared. Other steps of the method for manufacturing the display substrate are the same as those in the above embodiments, and are not described herein again.

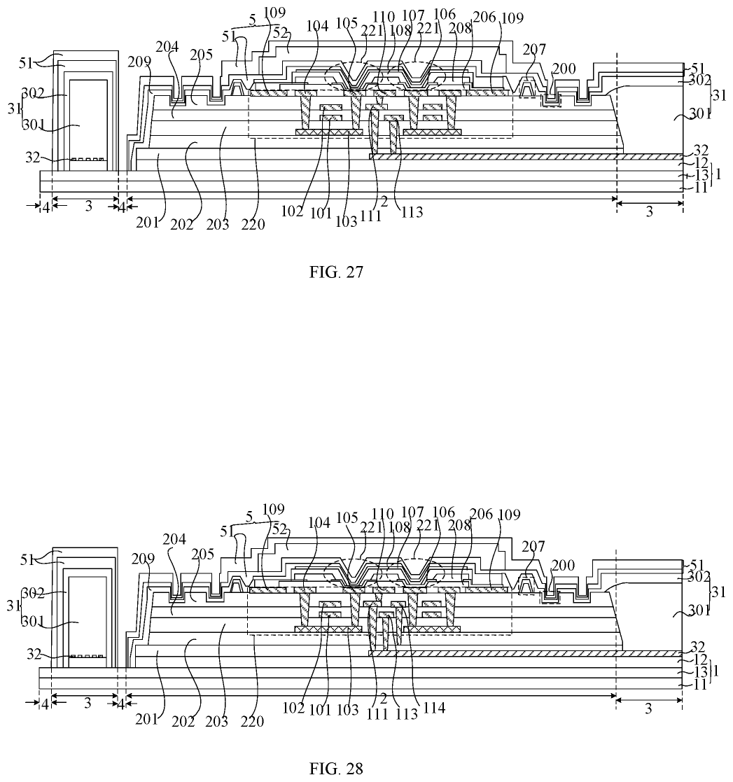

An embodiment of the present disclosure further provides a display substrate, which is different from that in the embodiment described above in that, as shown in FIG. 27, on the basis of any embodiment described above, the driving circuit 220 further includes a sixth electrode 113, the sixth electrode 113 is disposed between the first gate insulating layer 203 and the second gate insulating layer 204, and the sixth electrode 113 and the first gate electrode 101 are made of a same material and electrically connected; the conductive connecting part 32 further includes the scan line including a first scan line, and the first scan line extending from the area where the connection unit 3 is located to the area where the display unit 2 is located is electrically coupled to the sixth electrode 113 through via holes formed in the first insulating layer 201, the buffer layer 202, and the first gate insulating layer 203.

With such an arrangement, the first scan line is electrically coupled to the sixth electrode 113 without climbing a high step formed by the first insulating layer 201, the buffer layer 202 and the first gate insulating layer 203, so that the situation that the first scan line is broken when climbing over the high step can be improved or avoided, and meanwhile, since the display unit 2 is substantially not affected by the tensile stress, the via hole formed in the display unit 2 is also substantially not affected by the tensile stress in the process of stretching the display substrate, thereby improving or avoiding the situation that the first scan line is prone to be pulled apart when the display substrate is stretched.

In some implementations, as shown in FIG. 28, the driving circuit 220 further includes a seventh electrode 114, the seventh electrode 114 is disposed between the second gate insulating layer 204 and the intermediate dielectric layer 205, and the seventh electrode 114 and the second gate electrode 102 are made of a same material and electrically connected; the scan line further include a second scan line extending from the area where the connection unit 3 is located to the area where the display unit 2 is located, and the second scan line is electrically coupled to the seventh electrode 114 through via holes formed in the first insulating layer 201, the buffer layer 202, the first gate insulating layer 203, and the second gate insulating layer 204.

With such an arrangement, the second scan line is electrically coupled to the seventh electrode 114 without climbing a high step formed by the first insulating layer 201, the buffer layer 202, the first gate insulating layer 203, and the second gate insulating layer 204, so that the situation that the second scan line is prone to be broken when climbing the high step is improved or avoided, and meanwhile, since the display unit 2 is not affected by the tensile stress, the via hole formed in the display unit 2 is also not affected by the tensile stress during the stretching of the display substrate, thereby improving or avoiding the situation that the first scan line is prone to be pulled apart when the display substrate is stretched.

Other structures of the display substrate in this embodiment are the same as those in the above embodiments, and are not described herein again.

In the method for manufacturing the display substrate in this embodiment, only the pattern of the via hole needs to be formed when the pattern of the corresponding insulating layer is formed, the sixth electrode needs to be simultaneously formed when the first gate is manufactured, and the seventh electrode needs to be simultaneously formed when the second gate is manufactured. Other steps of the method for manufacturing the display substrate are the same as those in the above embodiments, and are not described herein again.

According to each display substrate provided by the embodiments of the present disclosure, the hollowed-out unit is arranged on the base substrate, so that most of the tensile stress of the display substrate can be released when the display substrate is stretched; by enabling the conductive connecting part to be in contact with the base substrate, to extend from the area of the base substrate where the connection unit is located to the area of the base substrate where the display unit is located, and to be electrically coupled to the conductive part through the via hole formed in the first insulating part, compared with the design of the connection wiring part in the FIG. 1 in the related art, the conductive connecting part is electrically coupled to the conductive part without climbing a high step formed by the first insulating part, so that the situation that the conductive connecting part is broken when climbing the high step is improved or avoided, meanwhile, since the display unit is substantially not influenced by the tensile stress, the via hole arranged in the display unit is also substantially not influenced by the tensile stress in the stretching process of the display substrate, and the situation that the conductive connecting part is prone to be pulled apart when the display substrate is stretched can be improved or avoided; by making the tensile property of the second insulating part better than that of the first insulating part, the second insulating part with the better tensile property can form a good protection for the conductive connecting part, thereby further improving the tensile property of the connection unit and improving or avoiding the conductive connecting part from being broken due to the tensile stress when the display substrate is stretched.

In addition, compared with the design of the connection wiring part in FIG. 2 in the related art, each display substrate provided in the above embodiments of the present disclosure enables the conductive connecting part to be disposed on the base substrate and directly in contact with the base substrate, and when the base substrate has a good tensile property, the conductive connecting part with a certain tensile property can correspondingly generate strain along with the tensile strain of the base substrate when the display substrate is stretched, and compared with the case that another insulating film layer is further arranged between the connection wiring part and the base substrate shown in FIG. 2, since the another insulating film layer is also subjected to the tensile force and needs to release the tensile force applied thereto when the display substrate is stretched, the conductive connecting part inevitably needs to bear the stress released by the another insulating film layer, so that the conductive connecting part finally bears a larger superimposed tensile stress, and the conductive connecting part is prone to be broken due to the fact that the conductive connecting part cannot bear too large tensile stress, therefore, the display substrate provided in the above embodiment of the present disclosure can better improve the tensile property of the connection unit, and better improve or avoid the situation that the conductive connecting part is prone to be broken due to the tensile stress when the display substrate is stretched.

An embodiment of the present disclosure further provides a display panel, which includes the display substrate in any one of the above embodiments.

By adopting the display substrate in any of the above embodiments, the tensile property of the display panel is improved, a stretchable display of the display panel can be well realized, and the display quality of the display panel can be ensured.

An embodiment of the present disclosure further provides a display device, which includes the display panel in the above embodiment.

By adopting the display panel in the above embodiment, the tensile property of the display device is improved, a stretchable display of the display device can be well realized, and the display quality of the display device can be ensured.

The display device provided by the embodiment of the present disclosure can be any product or component with a display function, such as an OLED panel, an OLED television, an LED panel, an LED television, a Mini LED panel, a Mini LED television, a display, a mobile phone, and a navigator.

It will be understood that the above embodiments are merely exemplary embodiments employed to illustrate the principles of the present disclosure, and the present disclosure is not limited thereto. It will be apparent to those skilled in the art that various changes and modifications can be made therein without departing from the spirit and scope of the present disclosure, and these changes and modifications are to be considered within the scope of the present disclosure.

1. A display substrate, comprising a base substrate, and a display unit, a connection unit and a hollowed-out unit disposed on the base substrate, wherein the display unit, the connection unit and the hollowed-out unit are adjacent to each other;
the display unit comprises a first insulating part and a conductive part; the connection unit comprises a second insulating part and a conductive connecting part, the second insulating part is arranged on a side of the conductive connecting part away from the base substrate;
the conductive connecting part is in contact with the base substrate, extends from an area of the base substrate where the connection unit is located to an area of the base substrate where the display unit is located, and is electrically coupled to the conductive part through a via hole formed in the first insulating part;
the second insulating part has a tensile property superior to that of the first insulating part.

2. The display substrate according to claim 1, wherein the conductive part comprises a driving circuit and a light emitting element disposed on a side of the driving circuit away from the base substrate; the driving circuit is electrically coupled to the light emitting element for driving the light emitting element to emit light;
the conductive connecting part comprises at least one of a data line, a scan line, a power supply signal line and a control signal line;
the data line, the scan line, the power supply signal line and the control signal line are respectively electrically coupled to the driving circuit;
the data line is configured to provide a data signal for driving the light emitting element to emit light;
the scan line is configured to provide a scan signal for driving the light emitting element to emit light;
the power supply signal line is configured to provide a power supply signal for driving the light emitting element to emit light;
the control signal line is configured to provide a control signal for driving the light emitting element to emit light.

3. The display substrate according to claim 2, wherein the driving circuit comprises a driving transistor comprising a first gate electrode, a second gate electrode, an active layer, a source electrode, and a drain electrode; orthographic projections of the first gate electrode and the second gate electrode on the base substrate respectively fall into an orthographic projection of the active layer on the base substrate; orthographic projections of the source electrode and the drain electrode on the base substrate are respectively positioned at two opposite ends of the orthographic projection of the active layer on the base substrate;
the first insulating part comprises a first insulating layer, a buffer layer, a first gate insulating layer, a second gate insulating layer, an intermediate dielectric layer and a planarization layer which are sequentially stacked in a direction away from the base substrate;
the active layer is positioned between the buffer layer and the first gate insulating layer; the first gate electrode is positioned between the first gate insulating layer and the second gate insulating layer; the second gate electrode is positioned between the second gate insulating layer and the intermediate dielectric layer; the source electrode and the drain electrode are located between the intermediate dielectric layer and the planarization layer;
the light emitting element is arranged on a side of the planarization layer away from the base substrate, and comprises a first electrode, a light emitting functional layer and a second electrode which are sequentially stacked;
the drain electrode is electrically coupled to the first electrode through a via hole formed in the planarization layer.

4. The display substrate according to claim 3, wherein the conductive connecting part extending from the area where the connection unit is located to the area where the display unit is located is located between the first insulating layer and the base substrate;
the second insulating part comprises a second insulating layer, and the second insulating layer and the planarization layer are made of a same material.

5. The display substrate according to claim 4, wherein the driving circuit further comprises a third electrode disposed between the intermediate dielectric layer and the planarization layer, and the third electrode is electrically coupled to the drain electrode;
the conductive connecting part comprises the data line, and the data line extending from the area where the connection unit is located to the area where the display unit is located is electrically coupled to the third electrode through via holes formed in the first insulating layer, the buffer layer, the first gate insulating layer, the second gate insulating layer and the intermediate dielectric layer.

6. The display substrate according to claim 4, wherein the driving circuit further comprises a third electrode and a fourth electrode, the third electrode is disposed between the intermediate dielectric layer and the planarization layer, and the third electrode is electrically coupled to the drain electrode;
the fourth electrode is arranged between the first gate insulating layer and the second gate insulating layer, and the fourth electrode and the first gate electrode are made of a same material;
the conductive connecting part comprises the data line, the data line extending from the area where the connection unit is located to the area where the display unit is located is electrically coupled to the fourth electrode through via holes in the first gate insulating layer, the buffer layer and the first gate insulating layer, and the fourth electrode is electrically coupled to the third electrode through via holes in the second gate insulating layer and the intermediate dielectric layer.

7. The display substrate according to claim 4, wherein the driving circuit further comprises a third electrode and a fourth electrode, the third electrode is disposed between the intermediate dielectric layer and the planarization layer, and the third electrode is electrically coupled to the drain electrode;
the fourth electrode is arranged between the second gate insulating layer and the intermediate dielectric layer, and the fourth electrode and the second gate electrode are made of a same material;
the conductive connecting part comprises the data line, the data line extending from the area where the connection unit is located to the area where the display unit is located is electrically coupled to the fourth electrode through via holes in the first gate insulating layer, the buffer layer, the first gate insulating layer and the second gate insulating layer, and the fourth electrode is electrically coupled to the third electrode through a via hole in the intermediate dielectric layer.

8. The display substrate according to claim 4, wherein the driving circuit further comprises a third electrode, a fourth electrode and a fifth electrode, the third electrode is disposed between the intermediate dielectric layer and the planarization layer, and the third electrode is electrically coupled to the drain electrode;
the fourth electrode is arranged between the second gate insulating layer and the intermediate dielectric layer, and the fourth electrode and the second gate electrode are made of a same material;
the fifth electrode is arranged between the first gate insulating layer and the second gate insulating layer, and the fifth electrode and the first gate electrode are made of a same material;
the conductive connecting part comprises the data line, and the data line extending from the area where the connection unit is located to the area where the display unit is located is electrically coupled to the fourth electrode through via holes formed in the first insulating layer, the buffer layer, the first gate insulating layer and the second gate insulating layer; the fourth electrode is electrically coupled to the third electrode through a via hole formed in the intermediate dielectric layer;
the data line extending from the area where the connection unit is located to the area where the display unit is located is electrically coupled to the fifth electrode through via holes formed in the first insulating layer, the buffer layer and the first gate insulating layer, and the fifth electrode is electrically coupled to the third electrode through via holes formed in the second gate insulating layer and the intermediate dielectric layer.

9. The display substrate according to claim 5, wherein the driving circuit further comprises a sixth electrode, the sixth electrode is disposed between the first gate insulating layer and the second gate insulating layer, and the sixth electrode and the first gate electrode are made of a same material and electrically connected;
the conductive connecting part further comprises the scan line which comprises a first scan line, and the first scan line extending from the area where the connection unit is located to the area where the display unit is located is electrically coupled to the sixth electrode through via holes formed in the first insulating layer, the buffer layer and the first gate insulating layer.

10. The display substrate according to claim 9, wherein the driving circuit further comprises a seventh electrode disposed between the second gate insulating layer and the intermediate dielectric layer, and the seventh electrode and the second gate electrode are made of a same material and electrically connected;
the scan line further comprises a second scan line, and the second scan line extending from the area where the connection unit is located to the area where the display unit is located is electrically coupled to the seventh electrode through via holes formed in the first insulating layer, the buffer layer, the first gate insulating layer and the second gate insulating layer.

11. The display substrate according to claim 4, wherein the first insulating part further comprises a pixel defining layer and a protective layer, the pixel defining layer and the protective layer are disposed on a side of the planarization layer away from the base substrate, and the pixel defining layer and the protective layer are stacked sequentially in a direction away from the base substrate;
the pixel defining layer is configured to define an arrangement position of the light emitting element;
the second insulating part further comprises a third insulating layer, the third insulating layer is arranged on a side of the second insulating layer away from the base substrate, and the third insulating layer and the protective layer are made of a same material.

12. The display substrate according to claim 1, wherein a surface of the first insulating part on a side thereof away from the base substrate is substantially flush with a surface of the second insulating part on a side thereof away from the base substrate.

13. The display substrate according to claim 12, wherein the first insulating part is adjacent to the second insulating part, and an acute included angle between an adjacent surface of the first insulating part and the second insulating part and the base substrate is greater than or equal to 45° and less than 90°.

14. The display substrate according to claim 11, wherein a plurality of display units are disposed on the base substrate and are arranged in an array, and the connection unit is configured to connect adjacent ones of the display units along a row direction and a column direction of the array;
the hollowed-out unit is arranged between the display unit and the connection unit; the base substrate comprises a first sub-layer and a second sub-layer stacked on each other, the second sub-layer is closer to the display unit and the connection unit than the first sub-layer;
the hollowed-out unit comprises hollowed-out patterns arranged in the second sub-layer and in film layers on the second sub-layer, and orthographic projections of the hollowed-out patterns in the second sub-layer and in the film layers on the second sub-layer on the first sub-layer are at least partially overlapped.

15. The display substrate according to claim 14, further comprising an encapsulation layer disposed on a side of the display unit and the connection unit away from the base substrate, wherein the encapsulation layer encapsulates the display unit and the connection unit;
a part of the encapsulation layer, which forms encapsulation for the display unit, is a first part, and a part of the encapsulation layer, which forms encapsulation for the connection unit, is a second part;
the first part has a thickness greater than that of the second part.

16. The display substrate according to claim 15, wherein in the display unit, an orthographic projection of the intermediate dielectric layer on the base substrate covers an entire area where the display unit is located;
a part of an orthographic projection of the planarization layer on the base substrate is not overlapped with the orthographic projection of the intermediate dielectric layer on the base substrate, a plurality of grooves are formed in the intermediate dielectric layer at a side thereof away from the base substrate, and the grooves are located in an area of the intermediate dielectric layer, an orthographic projection of which on the base substrate is not overlapped with the orthographic projection of the planarization layer on the base substrate;
parts of the protective layer and the encapsulation layer corresponding to the grooves are embedded in the grooves.

17. The display substrate according to claim 1, wherein the conductive connecting part is made of any one of Ti, Al, Mo, Ag, ITO, IZO, ZnO, In₂O₃, IGO, AZO, rubber mixed with conductive particles, and carbon nanotubes.

18. The display substrate according to claim 4, wherein the second insulating layer is made of any one of a general-purpose polymer of polymethylmethacrylate and polystyrene, a phenol group-based polymer derivative, an acryl-based polymer, a p-xylene-based polymer, an arylene ether-based polymer, an amide-based polymer, a fluoride-based polymer, and a vinyl alcohol-based polymer, or a mixture of two or more thereof.

19. (canceled)

20. (canceled)

21. (canceled)

22. A display panel, comprising the display substrate according to claim 1.

23. A display device, comprising the display panel according to claim 22.
